(19) United States
(12) Patent Application Publication
(10) Pub. No.: US 2023/0301164 A1
(43) Pub. Date: Sep. 21, 2023

(54) METHOD FOR IMPROVING STABILITY OF PEROVSKITE SOLAR CELLS

(71) Applicant: SOOCHOW UNIVERSITY, Suzhou (CN)

(72) Inventors: Jianxin TANG, Suzhou (CN); Yanqing LI, Suzhou (CN); Li CHEN, Suzhou (CN); Jingde CHEN, Suzhou (CN)

(21) Appl. No.: 18/010,154

(22) PCT Filed: Nov. 26, 2020
(86) PCT No.: PCT/CN2020/131970

§ 371 Date: Dec. 13, 2022

(30) Foreign Application Priority Data
Jun. 27, 2020 (CN) 202010593696.9

(51) Int. Cl. H10K 71/15; H01G 9/00; H10K 85/50

(52) U.S. Cl. CPC H10K 71/15; H01G 9/0029; H10K 85/50; H10K 30/50

(57) ABSTRACT

A method for improving the stability of perovskite solar cells includes: adding iodoformamidine and cesium iodide to a solvent and stirring, adding bromomethylamine and stirring, adding lead iodide and 3,4-dichloroaniline and stirring, obtaining a perovskite precursor solution for improving the stability of perovskite solar cells, spin-coating the perovskite precursor solution for improving the stability of perovskite solar cells onto a substrate, and performing thermal annealing to obtain a light absorption layer of a solar cell. A solar cell prepared with said perovskite layer solves the defects of existing perovskite technology, providing a means for improving the stability of perovskite for use in the preparation of batteries that has low processing environment requirements and a convenient preparation method, and can maintain stable properties in an ordinary environment for a long time.

### TECHNICAL FIELD

The present invention relates to solar technology, and specifically to a perovskite precursor solution for improving the stability of a perovskite solar cell.

### BACKGROUND

As a stable clean energy source, solar energy has become a research focus of global scientific and industrial research. In today’s solar cell market, silicon crystalline solar cells occupy a large share. After a long period of exploration and development, solar cells with silicon crystal as the core can have good and stable photoelectric conversion efficiency, but the shortcomings, such as high manufacture, maintenance and recycling costs, strict preparation condition, low recycling efficiency and low recycling cost, remain. A new generation of photoelectric conversion materials has emerged. Among them, perovskite material-based solar cells based on the ABX₃ structure (A represents cation methylamine, formamidine, metal cesium, etc.; B represents metal cations such as lead, tin, bismuth, etc.; X represents a halogen) have great development potential. The perovskite light-absorbing layer of positive phase crystal structure is the core of this type of solar cell. Compared with other optoelectronic materials, the light-absorbing layer of this perovskite solar cell has low cost, simple and fast manufacturing process, large open circuit voltage, and high spectral density. The photoelectric conversion efficiency of this kind of perovskite solar cell is higher than that of other solar cells. However, this material also has drawbacks. The material has high sensitivity to humidity and temperature. For example, the perovskite solar cell of a single-phase mixed cation system needs to be prepared in an anhydrous and oxygen-free low-temperature environment during the preparation process. When in use, if it is affected by fluctuations in environmental factors, the performance of battery devices will be greatly depleted. At present, the research on this material has made some progress, but the industrialization and the stability of the device still need to be developed.

### Technical Problem

The objective of the present invention is to provide a perovskite precursor solution for improving the stability of a perovskite solar cell in order to overcome the defects in the existing perovskite mineralization technology and to realize a perovskite stability improvement means for maintaining a stable long-term character in a common environment.

### Technical Solution

The present application adopts the following technical scheme: a method for improving the stability of the perovskite solar cell includes using a perovskite precursor for improving the stability of the perovskite solar cell to prepare a perovskite layer of the perovskite solar cell, so that the stability of the perovskite solar cell is improved. The perovskite precursor solution for improving the stability of the perovskite solar cell includes a perovskite precursor for improving the stability of the perovskite solar cell and a solvent. The perovskite precursor for improving the stability of the perovskite solar cell includes bromomethylamine, iodoformamidine, lead iodide, cesium iodide and 3,4-dichloroaniline; and an amount of 3,4-dichloroaniline is 0.6% -1.15% of an amount of brommethylamine, iodo-formamidine, lead iodide, cesium iodide and cesium iodide.

The perovskite precursor solution for improving the stability of the perovskite solar cell disclosed by the invention is composed of a perovskite precursor for improving the stability of the perovskite solar cell; the perovskite precursor for improving the stability of the perovskite solar cell includes bromomethylamine, iodoformamidine, lead iodide, cesium iodide and 3,4-dichloroaniline. An amount of 3,4-dichloroaniline is 0.63-1.12%, preferably 0.8-1.05%, of an amount of brommethylamine, iodo-formamidine, lead iodide, cesium iodide and cesium iodide. The solvent is a mixture of a sulfone solvent and an amide solvent, such as N,N-dimethylformamide and dimethyl sulfoxide; preferably, 70% -90% by volume of N,N-dimethylformamide and 10% -30% of dimethyl sulfoxide.

The invention further discloses a perovskite solar cell, which includes a perovskite layer, and the perovskite layer is prepared from the perovskite precursor for improving the stability of the perovskite solar cell. In the present invention, the perovskite solar cell further includes a conventional substrate, an electron transport layer, a hole transport layer, and electrodes, which are all conventional materials and structures.

In the present invention, bromomethylamine, iodo-formamidine, lead iodide, cesium iodide, and cesium iodide are 100%, bromomethylamine is 1% -5%, iodoformamidine is 10% -28%, lead iodide is 50% -80%, cesium iodide is balance; preferably, bromomethylamine is 1.5% -2%, iodoformamidine is 17% -22%, lead iodide is 65% -75%, cesium iodide is balance.

In the perovskite precursor solution for improving the stability of the perovskite solar cell, a weight ratio of the perovskite precursor for improving the stability of the perovskite solar cell to the solvent is 1: (0.8-1.5).

Preferably, in the perovskite precursor for improving the stability of the perovskite solar cell, an amount of bromomethylamine, iodo-formamidine, lead iodide and cesium iodide is 100%, the mass percentage, bromomethylamine is 1.83%, iodoformamidine is 20.16%, lead iodide is 71.91%, and cesium iodide is balance, 3, 4-dichloroaniline is 1.02%. Additionally, dimethyl sulfoxide and N, N-dimethylformamide are added to the perovskite precursor for improving the stability of the perovskite solar cell, so as to obtain the preferred perovskite precursor solution for improving the stability of the perovskite solar cell.

The perovskite precursor solution for improving the stability of the perovskite solar cell disclosed by the invention can improve the stability of the perovskite solar cell. The method of preparing the perovskite solar cell includes the following steps: spin-coating the perovskite precursor solution for improving the stability of the perovskite solar cell on a substrate, performing thermal annealing to obtain a light absorption layer of the solar cell, preparing a hole transport layer on the light absorption layer, and evaporating an electrode on the hole transport layer to obtain the perovskite solar cell. Spin-coating includes two steps, spin-coating at a speed of 1000 rpm for 10 seconds, spin-coating at a speed of 6000 rpm for 30 seconds, and dropwise adding diethyl ether before spin coating is finished.

The present application provides a method for improving the stability of the perovskite solar cell. The perovskite layer of the perovskite solar cell is prepared from the perovskite precursor for improving the stability of the perovskite solar cell, so that the stability of the perovskite solar cell is improved. The inventive step involves replacing the existing perovskite precursor with the new perovskite precursor for preparing the perovskite layer for the solar cell, so that the stability of the perovskite solar cell can be effectively improved.

### Beneficial Effect

The present invention discloses, for the first time, a perovskite precursor solution for improving the stability of perovskite solar cells containing 3,4-dichloroaniline. The examples show that the additives have an optimized effect on perovskite, and this optimization result shows that the untreated perovskite crystal has a poor uniformity and the size of the grains is not uniform and the treated perovskite crystal has a good uniformity and the size of the grains is uniform. The photoelectric conversion efficiency of treated perovskite crystal is significantly higher than the photoelectric conversion efficiency of the untreated perovskite device. The open-circuit voltage or the short-circuit current density, these conventional parameters for measuring the performance of the solar cell, are also greatly improved after the perovskite is modified. Specifically, the solar cell life test results show that after the 3,4-dichloroaniline is added, the stability of the perovskite solar cell is greatly improved.

### BRIEF DESCRIPTION OF THE DRAWINGS

FIG. 1 shows morphology contrast of perovskite crystals that were not treated and treated with 3,4-dichloroaniline (scale: 200 nm).

FIG. 2 shows a comparison result of the photoelectric conversion efficiency of the perovskite solar cell treated by 3,4-dichloroaniline and the photoelectric conversion efficiency of the untreated perovskite solar cell.

FIG. 3 shows a comparison result of the stability of the untreated perovskite solar cell and the stability of the perovskite solar cell treated with 3,4-dichloroaniline treatment.

### EMBODIMENTS OF THE INVENTION

The perovskite precursor for improving the stability of the perovskite solar cell includes bromomethylamine, iodoformamidine, lead iodide, cesium iodide and 3,4-dichloroaniline. Then, N,N-dimethylformamide and dimethyl sulfoxide are added to obtain a perovskite precursor solution for improving the stability of the perovskite solar cell.

The method of preparing the perovskite precursor solution for improving the stability of the perovskite solar cell includes the following steps: mixing brommethylamine, iodoformamidine, lead iodide, cesium iodide and 3,4-dichloroaniline with a solvent to obtain the perovskite precursor solution for improving the stability of the perovskite solar cell; preferably, adding methyl iodide and cesium iodide into a solvent, stirring, adding methyl bromide, stirring, adding lead iodide, 3, 4-dichloroaniline, and stirring to obtain the perovskite precursor solution for improving the stability of the perovskite solar cell.

All the starting materials are weighed in a glove box, and magnetic stirring is used in the stirring process.

All the starting materials of the present invention are commercially available products, and are conventional products for solar cells; and the related testing method is a conventional method in the art. For example, the method for testing the photoelectric conversion efficiency of the perovskite solar cell includes: placing the prepared battery in a solar cell test box, linking the test box with a digital source table Keithley-2400, opening test software, fixing the open-circuit voltage test range between -0.1 V -1.2 V, enabling the test range of the short-circuit current to be 0 mA/cm² - 30 mA/cm², opening the Newport sunlight simulator, and modulating the illumination power to AM1.5 (equivalent to one standard sun light). The corresponding matching test software is turned on to test the photoelectric conversion efficiency of the perovskite solar cell. During testing, the humidity and temperature of the environment are not controlled, and the specific humidity and temperature are changed according to the atmosphere environment atmosphere.

The method for testing the stability of the perovskite solar cell includes the following steps: placing the battery in a solar cell test box, wherein the test box is not additionally protected, so that the perovskite solar cell is exposed in air, keeping the humidity and the temperature consistent with the humidity and temperature in the atmospheric environment, and meanwhile, placing the test box in a standard sunlight, and performing a photoelectric conversion efficiency test on the perovskite solar cell every 12 hours. When the photoelectric conversion efficiency value of the perovskite solar cell to be unmodified is less than 1%, the service life test is stopped.

Example 1: The perovskite precursor solution for improving the stability of perovskite solar cells included: 14.1 mg of bromomethylamine, 155.4 mg of iodoformamidine, 554.3 mg of lead iodide, 47 mg of cesium iodide, 7.86 mg (i.e., 1.02%) of 3,4-dichloroaniline, 200 mL of dimethyl sulfoxide, 800 mL of N,N-dimethylformamide.

The preparation method included: (1) N,N-dimethylformamide was added into dimethyl sulfoxide, and the solution was stirred uniformly.

(2) Iodoformamidine and cesium iodide were weighed, added to the solution of step (1), stirred for 10 min, then bromomethylamine was added to the solution, the temperature of the solution was increased to 50° C., and stirring was performed for 10 min.

(3) Lead iodide was added into the solution prepared in step (2), and then 3,4-dichloroaniline was added into the solution and stirring until the solution was dissolved; and the solution was kept at a constant temperature of 50° C. throughout the stirring process.

(4) the solution prepared in step (3) was continuously stirred at 50° C. for 12 hours to obtain a perovskite precursor solution for improving the stability of the perovskite solar cell.

The present application provided a perovskite precursor for improving the stability of the perovskite solar cell and an application of the perovskite precursor for improving the stability of the perovskite solar cell. The stability of the perovskite solar cell can be improved.

The above 3,4-dichloroaniline was replaced with 3,5-dichloroaniline, and the rest was unchanged to obtain an isomer perovskite precursor solution.

The amount of the 3,4-dichloroaniline described above was changed to 4.62 mg (0.6%), and the rest are unchanged, so as to obtain a deficient perovskite precursor solution.

The amount of the 3,4-dichloroaniline described above was changed by 8.87 mg (1.15%), and the rest are unchanged, so as to obtain an excess perovskite precursor solution.

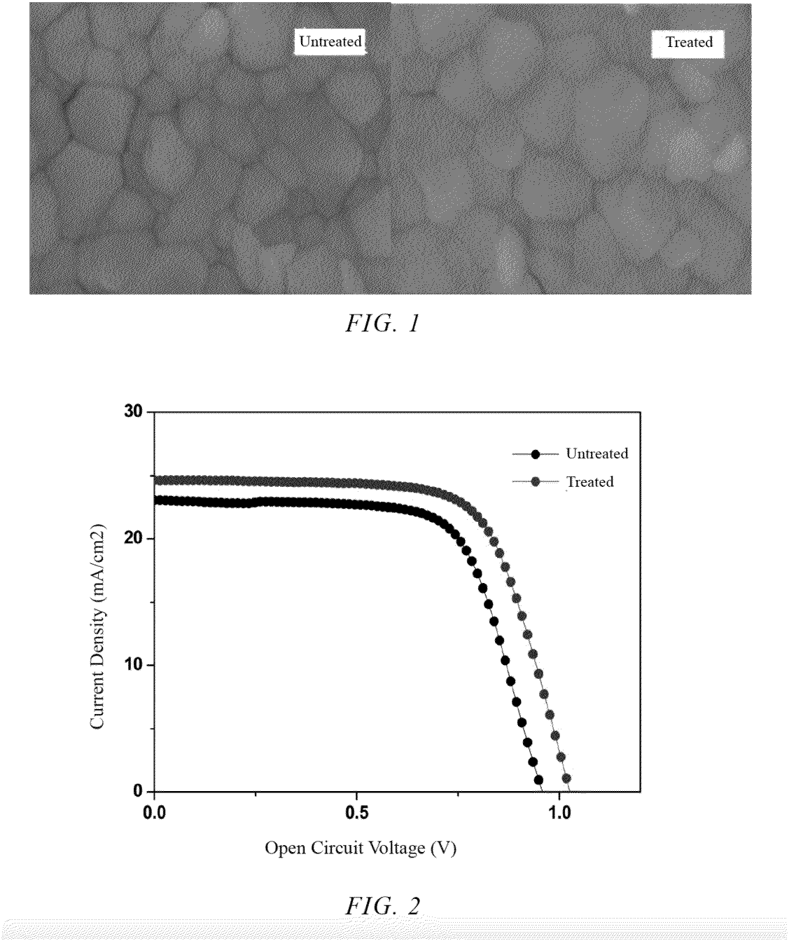

Example 2: The method for preparing the light absorption layer of the solar cell included: spin-coating the perovskite precursor solution for improving the stability of the perovskite solar cell in Example 1 on a substrate, and performing thermal annealing at 150° C. for 30 minutes to obtain the light absorption layer of the solar cell. The crystal morphology is shown in FIG. 1. Spin-coating included two steps, spin-coating at a speed of 1000 rpm for 10 seconds, spin-coating at a speed of 6000 rpm for 30 seconds, and dropwise adding 200 microliters of diethyl ether onto the rotating perovskite film at 15 seconds before spin coating.

The substrate was FTO glass coated with TiO₂ or ITO glass with SnO₂; the above operations were performed in the glove box with a water and oxygen content of less than 2 ppm.

Example 3: The perovskite solar cell included a conventional substrate, an electron transport layer, a hole transport layer, an electrode and a perovskite layer. The perovskite layer was prepared from the perovskite precursor solution for improving the stability of the perovskite solar cell in Example 1.

The method of preparing the solar cell included the following steps: spin-coating the perovskite precursor solution for improving the stability of the perovskite solar cell in Example 1 on a substrate, carrying out thermal annealing at 150° C. for 30 minutes to obtain a light absorption layer of the solar cell, spin-coating into two steps, spin-coating at a speed of 1000 rpm for 10 seconds, spin-coating at a speed of 6000 rpm for 30 seconds, and dropwise adding diethyl ether before spin coating was finished; then preparing a hole transport layer on the light-absorbing layer, then placing the prepared device in a high-vacuum electrode vapor deposition instrument, evaporating a 110-nanometer thick silver electrode layer on the hole transport layer, and finally obtaining a perovskite solar cell. In the technical solution of the present invention, the perovskite precursor solution for improving the stability of the perovskite solar cell was subjected to immediate annealing treatment after spin-coating was completed, without the need for vacuum treatment or other pre-annealing volatile solvents in the prior art.

The substrate was FTO glass coated with TiO₂ or ITO glass with SnO₂, and was an existing product. The thickness of the electron transport layer TiO₂ or SnO₂ was 100 nm; the preparation was conducted in the glove box, the water and oxygen content was lower than 2 ppm.

Specifically, the specific preparation method of the solar cell included: (1) spin-coating the perovskite precursor solution of the first example on the FTO glass (or ITO glass) treated in step (1) at a speed of 1000 rpm at a speed of 1000 rpm for 30 seconds, and dropwise adding 200 microliters of diethyl ether onto the rotating perovskite film at 15 seconds before spin coating, and transferring the FTO glass (ITO glass) with the perovskite film after spin coating to a plate at 150° C. for annealing for 30 minutes.

(2) Spin-coating a hole transport layer material (Spiro-OMeTAD, 2,2′,7,7′-tetra [N,N-bis(4-methoxyphenyl)amino]-9,9′-spirobifluorene solution) on the FTO glass treated in step (1), with a thickness of 80 nm, placing in a saturated oxygen environment for 1 min after spin coating, so as to obtain the solar cell semi-finished product, and then placing the prepared device in a high vacuum electrode vapor deposition instrument, evaporating a 110 nm thick silver electrode layer on the hole transport layer, and finally obtaining a perovskite solar cell complete device.

Hole Transport Layer Solution Preparation: 72.3 mg of Spiro-OMeTAD (2,2′,7,7′-tetra [N,N-bis(4-methoxyphenyl)amino]-9,9′-spirobifluorene solution) was dissolved in ultra-dried chlorobenzene, 28.8 microliters of TBP (4-tert-butylpyridine) was added dropwise to a chlorobenzene solution containing Spiro-OMeTAD, and 17.5 microliters of Li-TFSI solution (520 mg/ml and acetonitrile as a solvent) was added dropwise into the chlorobenzene solution, and mixed and stirred for 8 hours to obtain a hole transport layer solution.

Comparing Solar Cells: Conducting Example 1, with 3, 4-dichloroaniline not added, and the balance not changed, to obtain a comparison perovskite precursor solution.

Conducting Example 3, the perovskite precursor solution for improving the stability of the perovskite solar cell according to Example 1 of the perovskite precursor was replaced with the comparison perovskite precursor solution, and the rest was not changed to obtain a comparison solar cell.

Performance comparison: FIG. 1 shows the morphology and contrast ratio of untreated perovskite crystal and perovskite crystal treated with 3,4-dichloroaniline (scale: 200 nm). The uniformity of the untreated perovskite crystal was poor, and the sizes of the untreated crystal grains were different. The size of the treated perovskite crystal grain was almost similar, and the uniformity was good. The fluctuation degree of the surface of the untreated perovskite film was also larger than the fluctuation degree of the treated perovskite film.

FIG. 2 shows the photoelectric conversion efficiency of perovskite solar cells (Example 3, FTO) treated by 3,4-dichloroaniline and the photoelectric conversion efficiency of untreated perovskite solar cells (comparison solar cells and FTO). The photoelectric conversion efficiency of untreated perovskite devices was significantly lower than the photoelectric conversion efficiency of perovskite devices treated with 3,4-dichloroaniline. conventional parameters for measuring the performance of the solar cell, open-circuit voltage, the short-circuit, and filling factor, were greatly improved after the perovskite was modified. Therefore, the additive has an optimized effect on perovskite.

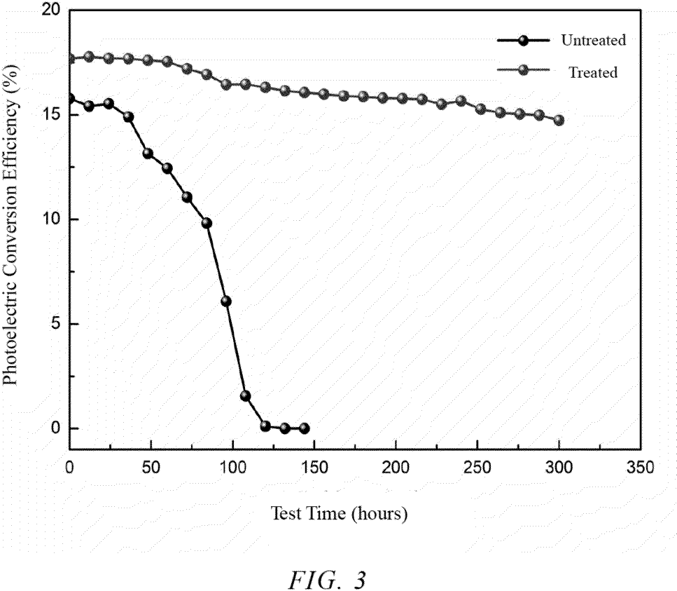

FIG. 3 shows a comparison of stability test result (500 hours, humidity: 50%, temperature: 25° C.) of an untreated perovskite solar cell (Comparative Solar Cell, FTO) and a perovskite solar cell treated 3,4-dichloroaniline (Example 3, FTO). After 3,4-dichloroaniline was added, the stability of the perovskite solar cell was greatly improved.

Comparative Example: the perovskite precursor solution for improving the stability of the perovskite solar cell of Example 3 was replaced with the isomer perovskite precursor solution, and the rest was unchanged. The obtained isomer solar cell (FTO) was tested for same stability, and its photoelectric conversion efficiency was reduced from 15.02% of initial (0 h) to 12.58% of 100 h.

The perovskite precursor solution for improving the stability of the perovskite solar cell of Example 3 was replaced with the less perovskite precursor solution, and the rest was unchanged, to obtain an isomer solar cell (FTO). The photoelectric conversion efficiency was reduced from 15.33% of initial (0 h) to 5.68% of 100 h in the same stability test.

The perovskite precursor solution for improving the stability of the perovskite solar cell in Example 3 was replaced with the excess perovskite precursor solution, and the rest was unchanged, to obtain an isomer solar cell (FTO). The photoelectric conversion efficiency was reduced from 14.86% of the initial (0 h) to 8.37% of 100 h in the same stability test.

Example 4: Chloride ions affected the film-forming performance of perovskite, and the composition of perovskite also had a key effect on perovskite film performance.

The perovskite precursor solution for improving the stability of the perovskite solar cell included 14.1 mg of bromomethylamine, 155.4 mg of iodoformamidine, 554.3 mg of lead iodide, 47 mg of cesium iodide, 7.32 mg (0.95%) of 3,4-dichloroaniline, 200 mL of dimethyl sulfoxide, and 800 mL of N,N-dimethylformamide, and the preparation method thereof was the same as Example 1.

The solar cell (ITO substrate) was then prepared according to Example 3, tested by the same stability test. The photoelectric conversion efficiency was reduced from 17.46% of initial (0 h) to 17.11% of 72 h, 16.03% of 100 h.

Example 5: Chloride ions affected the film-forming performance of perovskite, and the composition of perovskite also had a key effect on perovskite film performance.

The perovskite precursor solution for improving the stability of the perovskite solar cell included 14.1 mg of bromomethylamine, 155.4 mg of iodoformamidine, 524.3 mg of lead iodide, 77 mg of cesium iodide, 7.86 mg (1.02%) of 3,4-dichloroaniline, 200 mL of dimethyl sulfoxide, and 800 mL of N,N-dimethylformamide, and the preparation method of the perovskite precursor solution is the same as Example 1.

The solar cell (FTO substrate) was then prepared according to Example 3, tested by the same stability test. The photoelectric conversion efficiency was reduced from 17.39% of initial (0 h) to 17.02% of 72 h, 16.05% of 100 h.

In Example 5, 3,4-dichloroaniline was replaced with chlormethylamine (MAC1), and the rest was unchanged to obtain an isomer solar cell (FTO), which was tested in the same stability test. The photoelectric conversion efficiency was reduced from 16.93% of initial (0 h) to 14.39% of 72 h, 13.21% of 100 h.

In addition, the untreated perovskite had high humidity and temperature sensitivity to the environment, and high humidity and high temperature caused the untreated perovskite to decay and decompose in an extremely short time. The perovskite treated with 3,4-dichloroaniline had low humidity sensitivity, and can be stored for a long time in a high-humidity environment, which is also a great advantage of the present invention.

1-10. (canceled)

11. A method for improving the stability of a perovskite solar cell, comprising
preparing a perovskite precursor solution that includes a perovskite precursor and a solvent, the perovskite precursor includes bromomethylamine, iodoformamidine, lead iodide, cesium iodide and 3,4-dichloroaniline;
preparing a perovskite layer of the perovskite solar cell from the perovskite precursor solution; and
improving the stability of the perovskite solar cell.

12. The method according to claim 11, wherein an amount of bromomethylamine, iodoformamidine, lead iodide and cesium iodide is 100%; an amount of bromomethylamine is 1% -5%, an amount of iodoformamidine is 10% -28%, an amount of lead iodide is 50% -80%, an amount of cesium iodide is balance; and an amount of 3,4-dichloroaniline is 0.6% -1.15% of the amount of bromomethylamine, iodoformamidine, lead iodide, cesium iodide, and cesium iodide.

13. The method according to claim 11, wherein the solvent is a mixture of a sulfone solvent and an amide solvent.

14. The method according to claim 11, wherein an amount of brommethylamine, iodoformamidine, lead iodide and cesium iodide is 100%, an amount of bromomethylamine is 1% -5%, an amount of iodoformamidine is 10% -28%, an amount of lead iodide is 50% -80%, and an amount of cesium iodide is balance.

15. The method according to claim 11, further comprising:
spin-coating the perovskite precursor solution on a substrate;
performing a thermal annealing to obtain a light absorption layer of the perovskite solar cell;
preparing a hole transport layer on the light absorption layer; and
forming an electrode on the hole transport layer to obtain the perovskite solar cell.

16. The method according to claim 15, wherein spin-coating the perovskite precursor solution on the substrate comprises: spin-coating the perovskite precursor solution at a speed of 1000 rpm for 10 seconds, spin-coating the perovskite precursor solution at a speed of 6000 rpm for 30 seconds, and dropwise adding diethyl ether 15 seconds before spin coating is completed.

17. The method according to claim 13, wherein the solvent is a mixture of dimethyl sulfoxide and N,N-dimethylformamide.

18. The method according to claim 17, wherein a volume ratio of dimethyl sulfoxide and N,N-dimethylformamide is 1 : 4.

19. The method according to claim 11, wherein a weight ratio of the perovskite precursor and the solvent is 1: (0.8-1.5).

20. A perovskite solar cell prepared in accordance with the method of claim 11.
